(19) United States
(12) Patent Application Publication
(10) Pub. No.: US 2025/0066186 A1
(43) Pub. Date: Feb. 27, 2025

(54) ENVIRONMENTAL SENSOR AND METHOD FOR OPERATING AN ENVIRONMENTAL SENSOR

(71) Applicant: Robert Bosch GmbH, Stuttgart (DE)

(72) Inventors: David Slogsnat, Tuebingen (DE); Domenico Tangredi, Milano (IT); Joachim Kreutzer, Stuttgart (DE); Manuel Salvatore Santoro, Milan (IT); Massimiliano Musazzi, Como (IT)

(21) Appl. No.: 18/720,836

(22) PCT Filed: Jan. 30, 2023
(86) PCT No.: PCT/EP2023/052153

§ 371 Date: Jun. 17, 2024

(30) Foreign Application Priority Data
Mar. 8, 2022 (DE) 10 2022 202 295.5

(51) Int. Cl. B81B 7/00; B81C 99/00

(52) U.S. Cl. CPC B81B 7/0064; B81C 99/0035; B81B 2201/0257; B81B 2201/0264; B81B 2201/0292; B81B 2207/012; B81B 2207/07

(57) ABSTRACT

An environmental sensor. The environmental sensor includes: a MEMS element; an ASIC element electrically connected to the MEMS element by means of at least two bonding wires. T ASIC element includes an evaluation circuit designed to ascertain and evaluate a parasitic capacitance between the at least two bonding wires connected to pads of the MEMS element, in order to detect a material deposit on the environmental sensor.

### FIELD

The present invention relates to an environmental sensor. The present invention also relates to a method for operating an environmental sensor. The present invention furthermore relates to a computer program product.

### BACKGROUND INFORMATION

Pressure sensors are exposed to the external environment, which is why liquids may come into contact with them. This can result in offsets in pressure measurement values due to the increase in mass produced by the presence of the liquid itself.

Self-tests for sensors in which an excitation of a MEMS element is used to carry out a subsequent check of measurement values are conventional.

PCT Patent Application No. WO 2020/023414 A1 describes a method for liquid detection in a sensor environment and measures for removing the detected liquid. Disclosed is a capacitive water detection on a gel-filled sensor interior.

U.S. Pat. No. 10,640,367 B2, and U.S. Patent Application Publication Nos. US 2004/0108861 A1 and US 2019/0383688 A1 describe sensors comprising capacitive electrodes, which can be used to detect deposited liquid droplets on the basis of a changed dielectric constant of the environment.

U.S. Patent Application Publication No. US 2020/0064215 A1 combines the aforementioned approaches in that the water detection takes place via condensers and heating elements are used to evaporate the water droplet after it has been detected.

### SUMMARY

It is an object of the present invention to provide an improved environmental sensor.

According to a first aspect of the present invention, the object may be achieved with an environmental sensor comprising:
a MEMS element (MEMS: microelectromechanical system);
an ASIC element (ASIC: application-specific integrated circuit) electrically connected to the MEMS element by means of at least two bonding wires, wherein the ASIC element comprises an evaluation circuit designed to ascertain and evaluate a parasitic capacitance between the at least two bonding wires connected to pads of the MEMS element, in order to detect a material deposit on the environmental sensor.

In the environmental sensor, a parasitic capacitance, via which a presence of a material deposit can be detected, can be ascertained through a capacitance measurement by means of the evaluation circuit of the ASIC element using bonding wires electrically connected to the evaluation circuit.

Advantageously, already existing bonding wires of the environmental sensor can be used, whereby space and surface area can be saved. In this way, a presence of a material deposit, e.g., in the form of liquid, salt crust, etc., on the environmental sensor or on the MEMS element thereof can be ascertained. This exploits a permittivity that changes on the environmental sensor due to the material deposit, which can be accompanied by a change in the parasitic capacitance. An evaluation software may, for example, be hardwired in the ASIC element and can, for example, be used to carry out a self-test of the proposed environmental sensor in order to determine the functionality thereof.

According to a second aspect of the present invention, the object may be achieved with a method for operating an environmental sensor, wherein the environmental sensor comprises a MEMS element comprising a first pad and a second pad, wherein a first bonding wire is connected to the first pad and a second bonding wire is connected to the second pad, comprising the steps of:
applying an electrical actuation signal to the first bonding wire, wherein the first bonding wire is capacitively coupled to the second bonding wire;
ascertaining a parasitic capacitance formed between the bonding wires;
evaluating the ascertained parasitic capacitance; and
signaling a result of the evaluation.

The proposed method according to the present invention can be used in manufacturing or in the field, wherein, in the event of a fault, the environmental sensor (e.g., a crash sensor in the automotive field) is replaced in order thereby to avoid consequential damage.

According to a third aspect of the present invention, the object is achieved with a computer program product comprising program code means configured to carry out the proposed method according to the present invention when it runs on a proposed environmental sensor according to the present invention or is stored on a computer-readable data carrier.

Advantageous example embodiments and developments of the proposed environmental sensor of the present invention and of the proposed method of the present invention are disclosed herein.

According to an example embodiment of the present invention, the MEMS element can comprise a sensor structure or sensor circuit. This may include, for example, a capacitive Wheatstone bridge circuit.

With regard to the evaluation carried out by the evaluation circuit of the ASIC element, there is the possibility of carrying out the detection of the material deposit on the basis of the parasitic capacitance ascertained at a point in time or on the basis of an associated measurement value and/or on the basis of the parasitic capacitance ascertained over a period of time or on the basis of a plurality of associated measurement values. The period of time may be a specified period of time. With reference to the latter variant, the detection of the material deposit can take place on the basis of a temporal change of the ascertained parasitic capacitance. For example, if a significant change in capacitance occurs in a relatively short period of time, a material deposit can be detected. In contrast, a change taking place over a longer period of time (for example, years), for example due to aging effects, cannot be classified as the presence of a material deposit.

An advantageous development of the environmental sensor of the present invention provides that one of the pads of the MEMS element to which a bonding wire used for ascertaining the parasitic capacitance is connected is not functionally connected at the MEMS element.

A further advantageous development of the environmental sensor of the present invention provides that two pads of the MEMS element to which a bonding wire used for ascertaining the parasitic capacitance is respectively connected are not functionally connected at the MEMS element.

With reference to the aforementioned configurations in which the MEMS element comprises at least one pad not functionally connected at the MEMS element, the relevant pad may be a pad that is electrically not further connected or isolated, and may also be referred to as a blind terminal. Such a pad cannot be electrically connected to the sensor structure or sensor circuit of the MEMS element. Accordingly, a bonding wire connected to such a pad may be a bonding wire open at the MEMS element and may also be referred to as a blind line or blind wire. Such a bonding wire cannot be electrically connected to the sensor structure or sensor circuit of the MEMS element or to a ground or a ground potential.

A further advantageous development of the environmental sensor of the present invention provides that two pads of the MEMS element to which a bonding wire used for ascertaining the parasitic capacitance is respectively connected are functionally connected at the MEMS element. These pads may be further electrically connected at the MEMS element and may be electrically connected to at least one component of the MEMS element, such as the sensor structure or sensor circuit, or also to a ground potential. In this case, the pads may be terminal pads of the sensor structure or sensor circuit. Advantageously, already existing structures are used in this way. An effort to realize the proposed environmental sensor is thus optimized. This applies, for example, to the following configuration.

A further advantageous development of the environmental sensor of the present invention provides that two pads of the MEMS element to which a bonding wire used for ascertaining the parasitic capacitance is respectively connected are terminal pads of a capacitive Wheatstone bridge circuit of the MEMS element. The evaluation circuit is designed to ascertain the parasitic capacitance through a capacitance measurement relating to a reference capacitance of the capacitive Wheatstone bridge circuit. In this configuration, a driving signal for the Wheatstone bridge circuit can be used to ascertain the parasitic capacitance. The driving signal can be generated by the evaluation circuit and can be applied to one of the two bonding wires used for ascertaining the capacitance. This can also exploit the fact that the parasitic capacitance, which can exist between the two bonding wires, can be present in the form of a capacitance connected in parallel to the reference capacitance of the bridge circuit. In the capacitance measurement carried out by the evaluation circuit, a total capacitance can therefore be ascertained as the sum of the fixed reference capacitance and the parasitic capacitance, whereby the parasitic capacitance can be deduced. Ascertaining the total capacitance thus constitutes ascertaining the parasitic capacitance. According to the above statements, the detection of the material deposit can take place on the basis of the total capacitance ascertained at a point in time or on the basis of an associated measurement value and/or on the basis of the total capacitance ascertained over a period of time (i.e., a temporal change of the same) or on the basis of a plurality of associated measurement values.

Further advantageous developments of the environmental sensor of the present invention provide that the bridge circuit is a full bridge circuit or a half bridge circuit.

A further advantageous development of the environmental sensor of the present invention provides that the evaluation circuit is designed to use a defined capacitance value to determine that no material deposit at all is present on the environmental sensor. This can take place by comparing the ascertained parasitic capacitance or an associated measurement value to the defined capacitance value. The defined capacitance value may be a pre-known comparison value or threshold value.

The evaluation circuit can furthermore be designed to carry out a comparison using not only one but a plurality of different comparison values or threshold values. These different values can relate to different materials. In this way, there is the possibility of detecting different material deposits.

A further advantageous development of the environmental sensor of the present invention provides that the environmental sensor furthermore comprises a signaling device, by means of which a presence of a material deposit can be signaled. A user of the environmental sensor can thus recognize in a simple manner whether or not the environmental sensor is impaired in its proper functionality. The signaling device can be activated by the evaluation circuit of the ASIC element. The signaling may, for example, take place visually, audibly, and/or haptically.

A further advantageous development of the environmental sensor of the present invention provides that the evaluation circuit is designed to activate a device for removing liquid when liquid is detected. For example, in this case, a heater, a fan, or the like can be activated.

Further advantageous developments of the environmental sensor of the present invention provide that the environmental sensor is at least one of the following: liquid sensor, pressure sensor, gas sensor, humidity sensor, microphone. Advantageously, the proposed environmental sensor can be realized in a variety of forms.

With regard to the proposed method of the present invention, signaling may take place visually, audibly, and/or haptically. A signaling device of the environmental sensor can be activated for this purpose.

Furthermore, there is the possibility of carrying out the method of the present invention, or at least the steps of applying the electrical actuation signal, ascertaining the parasitic capacitance and evaluating, at defined points in time and/or cyclically.

The present invention is described in detail below with further features and advantages on the basis of several figures. The figures are primarily intended to illustrate the essential principles of the present invention.

Disclosed method features of the present invention result analogously from corresponding disclosed device features of the present invention, and vice versa. This means in particular that features, technical advantages and embodiments relating to the environmental sensor of the present invention result analogously from corresponding embodiments, features and advantages relating to the method for operating an environmental sensor according to the present invention, and vice versa.

### BRIEF DESCRIPTION OF THE DRAWINGS

FIG. 1 shows a cross-sectional view of an embodiment of a proposed environmental sensor, according to an example embodiment of the present invention.

FIG. 2 shows a cross-sectional view of an embodiment of a proposed environmental sensor with a highlighted detail view, according to an example embodiment of the present invention.

FIG. 3 shows a basic circuit diagram of a first embodiment of a proposed environmental sensor, according to an example embodiment of the present invention.

FIG. 4 shows a basic circuit diagram of a second embodiment of a proposed environmental sensor, according to an example embodiment of the present invention.

FIG. 5 shows a basic circuit diagram of a third embodiment of a proposed environmental sensor, according to an example embodiment of the present invention.

FIG. 6 shows a measurement diagram when liquid occurs on the environmental sensor, according to an example embodiment of the present invention.

FIG. 7 shows a time flowchart with a basic flow of a proposed method for operating an environmental sensor, according to an example embodiment of the present invention.

### DETAILED DESCRIPTION OF EXAMPLE EMBODIMENTS

Below, the proposed environmental sensor 100 is explained in more detail as a sensor comprising a capacitive measurement sensor system. In this case, the measured variable is detected on the basis of a MEMS element 10 in which both variable capacitances (active measuring elements) and reference capacitances are installed. In addition, the MEMS element 10 is protected by either gel or oil.

Proposed is a detection principle for detecting material deposits, in which the presence of a material deposit on the environmental sensor 100 is evaluated, wherein a capacitance variation of a capacitance between bonding wires between MEMS element 10 and ASIC element 20 is ascertained and evaluated for this purpose.

Below, a detection of a material deposit in the form of liquid, in particular water, is explained. Advantageously, however, the proposed method may also be used to detect other undesirable material deposits, such as particles, fibers, deposits, structures, biofilms, sweat, salt, etc. This capacitance variation is therefore measured on the basis of the pressure measurement chain, which is already implemented in the ASIC element 20.

Proposed is an environmental sensor 100, which may, for example, be designed as a barometric capacitive pressure sensor. In such a capacitive sensor, pressure is sensed by means of a MEMS element 10, in which both variable capacitances (the actual pressure measuring elements) and fixed reference capacitances are installed, and which are arranged in a capacitive Wheatstone bridge circuit.

Advantageously, the proposed method does not require a dedicated signal processing chain, but the detection of the material deposit can be achieved with a specific configuration of the ASIC element 20. In addition, the liquid detection is closer to the gel surface, i.e., where a liquid deposit is expected and the sensor performance is most affected, than in previous implementations. This proposed concept is thus well able to detect and/or quantify material deposits, as a result of which appropriate countermeasures can be taken in the case of a detection.

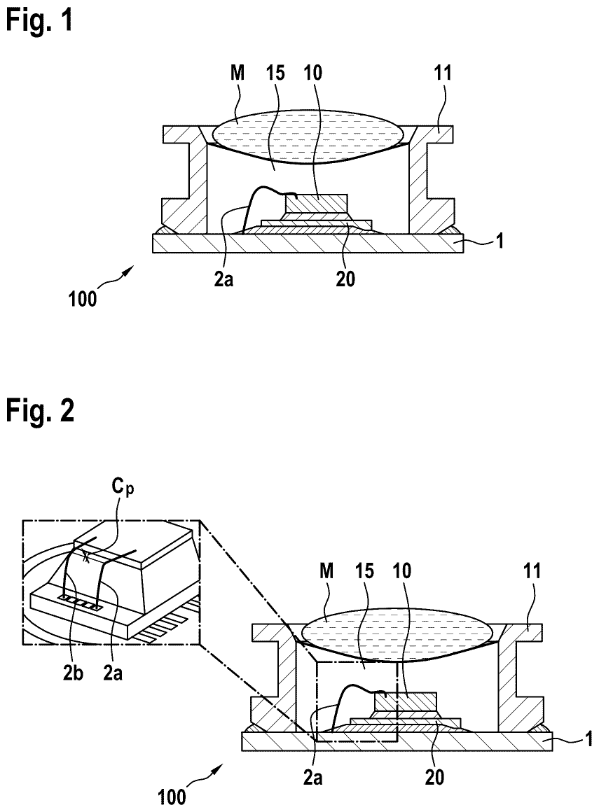

FIG. 1 shows a cross-sectional view of an embodiment of a proposed environmental sensor 100. It can be seen that an ASIC element 20 with which a signal evaluation can be carried out is on a substrate 1. A MEMS element 10 is arranged on the ASIC element 20. The ASIC element 20 and the MEMS element 10 can be realized in the form of semiconductor components or semiconductor chips. The ASIC element 20 and the MEMS element 10 are electrically connected to one another by means of at least two bonding wires 2a, 2b, which are connected to contact surface elements or contact elements of the MEMS and ASIC elements 10, 20, here referred to as bonding pads or pads. The environmental sensor 100 or the MEMS and ASIC elements 10, 20 are protected by means of a protection element 15 (e.g., gel). It can further be seen that a material deposit M, e.g., in the form of water, is on the top side of the protection element 15, which may impair a functionality of the environmental sensor 100. Instead of gel, oil buffer solutions (which are, for example, used in high-pressure applications, e.g., industrial or automotive applications) or air-permeable membrane solutions (established for microphones/acoustic transducers) may also be used as the protection element 15. The environmental sensor 100 in the form of a capacitive pressure sensor is furthermore covered by a cap element 11 (e.g., metal lid) and thereby additionally protected.

Other embodiments of the environmental sensor 100 (not shown in figures) with other arrangements of MEMS and ASIC elements 10, 20 are also possible.

The presence of water (or another deposited medium) changes a parasitic capacitance Cₚ between bonding wires 2a, 2b, which is ascertained and evaluated, wherein, on the basis of this evaluation, a presence of water (or of another medium) on the environmental sensor 100 is deduced.

The mentioned parasitic capacitance Cₚ forms between each two bonding wires 2a, 2b which are capacitively coupled to one another. The value of this capacitance Cₚ depends on the permittivity of the surrounding material. Water (and also other media) on the protection element 15 or even within the protection element 15 (if a medium is soluble in the protection element 15) can thus change a capacitance value of the parasitic capacitance Cₚ, which is exploited in the proposed method.

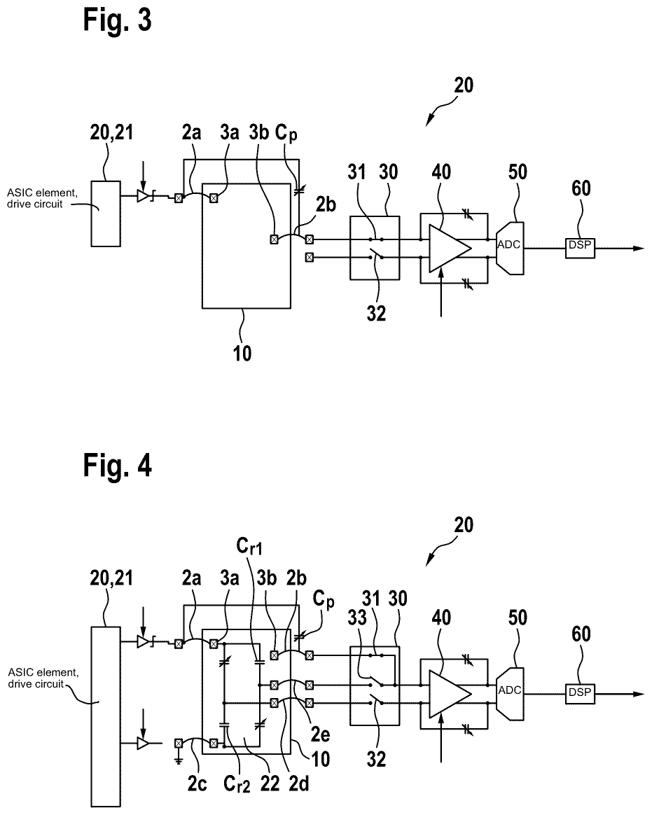

With the normal full bridge connection of the MEMS element 10, the changes in capacitance usually cancel out and cannot be detected in this way. In a possible realization of the proposed environmental sensor 100, as explained in more detail below with reference to FIG. 3, two dedicated bonding wires 2a, 2b are used, between which the considered parasitic capacitance Cₚ forms. The bonding wires 2a, 2b are open at the MEMS element 10, i.e., are connected to functionally not connected pads 3a, 3b of the MEMS element 10. The pads 3a, 3b which are functionally not connected at the MEMS element 10 thus constitute blind terminals, whereas the relevant bonding wires 2a, 2b constitute electrical blind lines or blind wires. The capacitance present between the bonding wires 2a, 2b can be read by an analog front end of the ASIC element 20. In another realization, there is only one unconnected or open bonding wire 2a, 2b leading to the MEMS element 10, and the considered capacitance Cₚ is formed between this bonding wire and another bonding wire which serves as a connection to the bridge circuit 22 or to a ground potential GND. This is explained in more detail below with reference to FIG. 4.

FIG. 2 shows the environmental sensor 100 of FIG. 1 with a highlighted detail view. In the highlighted detail view, it can be seen that a parasitic capacitance Cₚ has formed between the two bonding wires 2a, 2b shown. The parasitic capacitance Cₚ may have a different magnitude depending on the presence of material on the environmental sensor 100 and is ascertained and evaluated according to the proposed method.

In this context, a defined or pre-known capacitance value at which no material deposit at all is on the environmental sensor 100 can, for example, be used as the starting point. If other capacitance values of the parasitic capacitance Cₚ exist, which can be ascertained by means of the proposed measurement method, the presence of water, sweat, salt, or other materials on the environmental sensor 100 can be deduced, for example.

Advantageously, it is thereby simple to deduce a presence of material on the environmental sensor 100, which may be impaired in its functionality by the material and then, for example, activates a device for removing the material deposit, e.g., in the form of a heater, a fan, etc. (not shown). By removing the material deposit M, the proper functionality of the environmental sensor 100 can thus advantageously be restored. However, it is also possible to signal (e.g., visually, audibly, haptically) the presence of the material deposit M by activating a signaling device so that a user can take the initiative to remove the material deposit M from the environmental sensor 100.

With the normal full bridge circuit of the MEMS element 10, the changes in capacitance usually cancel out and/or cannot be distinguished from a change in pressure and therefore cannot be detected.

Possible realizations of the proposed environmental sensor 100 are explained in more detail below with reference to circuit diagrams.

In a first realization of the environmental sensor 100 shown in FIG. 3, two dedicated bonding wires 2a, 2b are used, between which the parasitic capacitance Cₚ has formed. The bonding wires 2a, 2b, which are also referred to as first bonding wire 2a and second bonding wire 2b below, are connected to pads 3a, 3b of the MEMS element 10, which are not functionally connected at the MEMS element 10, i.e., are not connected to a sensor circuit of the MEMS element 10 (Wheatstone bridge circuit) or to a ground potential. The capacitance Cₚ to be ascertained between the bonding wires 2a, 2b may, for example, be read by an analog front end of the ASIC element 20.

In the proposed method for operating the environmental sensor 100, an electrical actuation signal is applied to the first bonding wire 2a by means of a drive circuit 21. The first bonding wire 2a is capacitively coupled to the second bonding wire 2b so that the parasitic capacitance Cₚ exists between the two bonding wires 2a, 2b.

Shown is a switch device 30 comprising a switch element 31, which is electrically connected to the second bonding wire 2b and has been switched to a closed switching state for the measurement of the parasitic capacitance Cₚ. In this way, an electrical signal regarding the capacitance Cₚ to be ascertained can be transmitted via the switch element 31 to an amplification device 40 (e.g., low noise amplifier) and subsequently to an A/D converter 50 (ADC: analog-to-digital converter). By means of a subsequent digital signal processor 60 (DSP: digital signal processor), a capacitance value of the parasitic capacitance Cₚ can be ascertained from the signal. The mode of operation of such a signal processing chain is conventional and is therefore not explained in more detail here. The switch device 30, the amplification device 40, the A/D converter 50 and the digital signal processor 60, which are electrically connected to one another in a suitable way, are components of the ASIC element 20, just like the drive circuit 21.

Further configurations of the environmental sensor 100 are described below. Matching features as well as identical and identically acting components are not described in detail again below. For details in this respect, reference is instead made to the description above. Furthermore, aspects and details mentioned with respect to one configuration may also be used with respect to another configuration, and features of two or more configurations may be combined with one another.

In a further embodiment of the environmental sensor 100 shown in FIG. 4, there is only one unconnected or open bonding wire 2b, which is connected to a functionally not connected pad 3b of the MEMS element 10. In this case, the parasitic capacitance Cₚ to be ascertained is present between this second bonding wire 2b and a first bonding wire 2a. The first bonding wire 2a serves as a connection to the capacitive Wheatstone bridge circuit 22 of the MEMS element 10 and is connected to a pad 3a connected to the bridge circuit 22. The pad 3a forms a terminal pad of the bridge circuit 22. Advantageously, in this variant, the bonding wire 2a can be used as an electrical actuation line for the Wheatstone bridge circuit 22. It can be seen that, in this case, switch elements 32, 33 of the switch device 30 are open, via which capacitance values of the capacitive Wheatstone bridge circuit 22 via bonding wires 2d, 2e are read in normal operation for the purpose of a pressure measurement. The bonding wires 2d, 2e are connected to further terminal pads of the bridge circuit 22.

In the variants described here, barometric pressure is detected by means of the MEMS element 10 by implementing a fully capacitive bridge circuit in the form of the Wheatstone bridge circuit 22. Two elements of the bridge circuit 22 are variable capacitances and are used for pressure measurement. The other two elements are fixed capacitances Cᵣ₁, Cᵣ₂, which are used as reference capacitances. MEMS and ASIC elements 10, 20 are electrically connected to one another by a plurality of bonding wires 2a . . . 2e, which connect the ASIC element 20 and its drive circuit 21 to the bridge circuit 22. By means of the drive circuit 21 of the ASIC element 20, an electrical actuation signal is applied.

In the embodiment shown in FIG. 4, the switch element 31 of the switch device 30 connected to the second bonding wire 2b is closed, in a manner corresponding to FIG. 3, for the purpose of ascertaining the parasitic capacitance Cₚ. As a result, if an electrical actuation signal is applied to the first bonding wire 2a by means of the drive circuit 21, an electrical signal regarding the parasitic capacitance Cₚ can be transmitted via the switch element 31 to the signal processing chain comprising the amplification device 40, the A/D converter 50 and the digital signal processor 60. The digital signal processor 60 can then provide a capacitance value of the capacitance Cₚ.

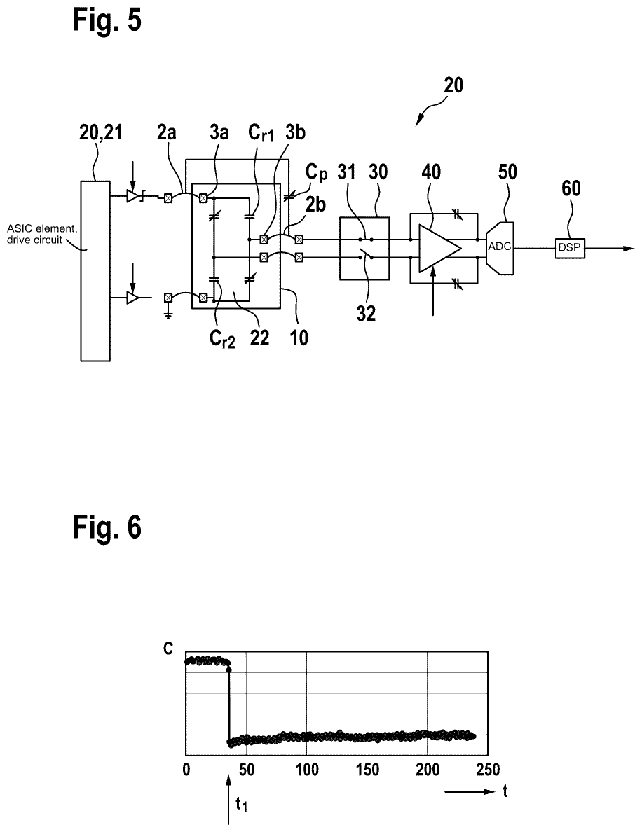

In a third embodiment of the proposed environmental sensor 100 shown in FIG. 5, two bonding wires 2a, 2b are used to ascertain the parasitic capacitance Cₚ, which are connected to the capacitive Wheatstone bridge circuit 22 of the MEMS element 10 and are used in normal operation of the environmental sensor 100 for pressure measurements. The bonding wires 2a, 2b are connected to pads 3a, 3b of the MEMS element 10, which are functionally connected at the MEMS element 10 and form terminal pads of the bridge circuit 22.

In the variant shown in FIG. 5, the parasitic capacitance Cₚ is ascertained on the basis of a capacitance measurement relating to the fixed reference capacitance Cᵣ₁ of the Wheatstone bridge circuit 22. In this case, it is exploited that the parasitic capacitance Cₚ present between the bonding wires 2a, 2b can act as a capacitance connected in parallel to the reference capacitance Cᵣ₁. In this respect, a total capacitance C in the form of a sum of the reference capacitance Cᵣ₁ and the parasitic capacitance Cₚ can be ascertained, i.e., according to the following formula:

$$C = {C}_{r 1} + {C}_{p} \qquad ( 1 )$$

with:
C . . . total capacitance
Cᵣ₁ . . . fixed reference capacitance of the Wheatstone bridge circuit
Cₚ . . . parasitic capacitance

Due to the fixed and known reference capacitance Cᵣ₁, the parasitic capacitance Cₚ can be deduced on the basis of the total capacitance C. Ascertaining the parasitic capacitance Cₚ thus takes place through or is equivalent to ascertaining the total capacitance C.

As shown in FIG. 5, for the purpose of measuring the total capacitance C and thus the parasitic capacitance Cₚ, the switch element 31 of the switch device 30 that is electrically connected to the second bonding wire 2b has been switched to a closed switching state in a manner corresponding to FIG. 3. In contrast, another switch element 32 of the switch device 30, which is closed in normal operation for pressure measurement, is in an open switching state. If an electrical actuation signal is applied to the first bonding wire 2a by means of the drive circuit 21, an electrical signal regarding the total capacitance C can in this way be transmitted via the switch element 31 to the signal processing chain comprising the amplification device 40, the A/D converter 50 and the digital signal processor 60. The digital signal processor 60 can then provide a capacitance value of the total capacitance C that depends on the magnitude of the parasitic capacitance Cₚ and/or a capacitance value of the parasitic capacitance Cₚ.

The aforementioned variant represents the most cost-efficient solution since it does not require any additional bonding wire and, as a result, bonding wire connections and silicon surface area can advantageously be saved. In order to detect a material deposit M, the environmental sensor 100 is thus only operated in a specific measurement mode, in which a measurement is only carried out with respect to one of the two reference capacitances Cᵣ₁, Cᵣ₂, i.e., the reference capacitance Cᵣ₁ in the present case, in comparison to a normal mode. In this case, the switch element 32 is open and the measurement of the total capacitance C takes place via the closed switch element 31.

The detection of a material deposit M on the environmental sensor 100 can take place on the basis of a measurement value of the parasitic capacitance Cₚ (or total capacitance C with reference to the configuration of FIG. 5). In this case, a comparison to a defined or pre-known capacitance value at which no material deposit at all is on the environmental sensor 100 can, for example, take place. Additionally, or alternatively, there is the possibility of carrying out the detection of a material deposit M on the basis of the parasitic capacitance Cₚ (or total capacitance C with reference to FIG. 5) ascertained over a period of time and, in this respect, on the basis of a plurality of measurement values thereof. In the event that a significant change in capacitance takes place in a relatively short period of time, a material deposit M can be detected.

An evaluation as described above can be carried out by the digital signal processor 60 of the ASIC element 20. If a presence of a material deposit M is detected by the signal processor 60 in this way, the signal processor 60 can then, for example, activate a signaling device for signaling the determined material deposit M and/or a device for removing the material deposit (not shown).

A detection of a material deposit M through a change in capacitance taking place over time is explained in more detail below with reference to the configuration of FIG. 5. In this sense, a material deposit can be ascertained through a measurement of the total capacitance C using the following formula:

$$C ( t ) = {C}_{r 1} + {C}_{p} ( t ) \qquad ( 2 )$$

with:
C . . . total capacitance
Cᵣ₁ . . . fixed reference capacitance of the Wheatstone bridge circuit
Cₚ . . . parasitic capacitance
t . . . time

For detecting the material deposit M, it is sufficient to detect a change in the measured total capacitance C, wherein a significant change in the total capacitance C ascertained in a defined short time allows a corresponding change in the parasitic capacitance Cₚ due to a material deposit M to be deduced. A detected change in the total capacitance C can be directly (for example, linearly) associated with a change in the parasitic capacitance Cₚ due to a material deposit M. Defined numerical values can be ascertained in the course of comparison measurements at the end of the manufacture and can take into account numerous circumstances (e.g., sensor model, batches, material properties, etc.).

This applies at least to individual measurements at defined points in time in a sufficiently short period of time (e.g., days, weeks, months) so that aging effects (e.g., drifts) over greater periods of time (e.g., years) advantageously cannot affect the measurements, if possible, so that material deposits are not inadvertently or incorrectly detected. For example, it is possible in this case to define a value of the total capacitance C at which no material deposit is present on the environmental sensor 100, wherein subsequent measurement values can be compared to this defined value of the total capacitance C in order to determine whether or not a material deposit M is now present on the environmental sensor 100.

FIG. 6 purely qualitatively shows, for illustrative purposes, a change in the total capacitance C when a drop of water is placed on the protection element 15 of the environmental sensor 100 at a point in time t₁. This is associated with a significant change in the parasitic capacitance Cₚ, and thus the total capacitance C, and can therefore be reliably detected on the basis of a corresponding capacitance measurement.

In the most general sense, the proposed detection principle applies to embodiments that differ from the aforementioned ones, i.e., to environmental sensors 100 comprising a different number of pads 3a . . . 3n and comprising different wire bonding connections between the MEMS element 10 and the ASIC element 20. In addition, the proposed method can also be applied to capacitive pressure sensors in half-bridge technology (not shown), i.e., in which only one fixed and one variable capacitance are implemented.

Finally, this measurement concept can be applied to all scenarios in which at least two bonding wires are present between the MEMS element 10 and the ASIC element 20, regardless of the purpose of these bonding wires 2a, 2b.

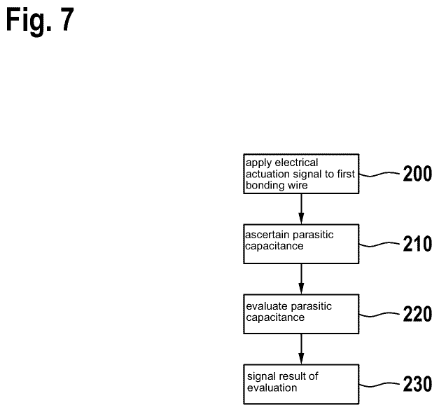

FIG. 7 shows a flowchart of a method for operating a proposed environmental sensor 100.

In a step 200, an electrical actuation signal is applied to the first bonding wire 2a, wherein the first bonding wire 2a is capacitively coupled to the second bonding wire 2b.

In a step 210, a parasitic capacitance Cₚ formed between the bonding wires 2a, 2b is ascertained.

In a step 220, the ascertained parasitic capacitance Cₚ is evaluated.

In a step 230, a result of the evaluation is signaled.

The proposed method can, for example, be performed in the form of a self-test during the production test in order to eliminate faulty environmental sensors 100. Optionally, it could also be performed later in the field in order to detect faults during the service life of the environmental sensor 100. In this case, a comparison value/threshold value can be stored in a non-volatile memory in the production unit. The comparison value/threshold value represents a capacitance value at which no material deposit at all is present on the environmental sensor 100. Comparison values or threshold values can preferably be ascertained for different materials so that different comparison values or threshold values can be used to detect different material deposits in a simple manner.

The proposed method can preferably be designed as software executed at least partially on the ASIC element 20 or at least partially externally thereof, whereby simple adaptability of the method is supported. Alternatively, the proposed method may be realized at least partially or even entirely in hardware.

Advantageously, the proposed method can be realized as a computer program that runs on the ASIC element 20 of the environmental sensor 100 or is stored on a computer-readable data carrier.

In summary, the present invention proposes an environmental sensor 100 and a method for operating an environmental sensor 100, with which a test for the presence of a material deposit M is possible in a simple manner, whereby advantageously a state of the environmental sensor 100 and an admissibility of measurement operations can be assessed.

The person skilled in the art will modify and/or combine the features of the present invention in a suitable manner without departing from the core of the present invention.

1-13. (canceled)

14. An environmental sensor, comprising:
a MEMS element; and
an ASIC element electrically connected to the MEMS element using at least two bonding wires, wherein the ASIC element includes an evaluation circuit configured to ascertain and evaluate a parasitic capacitance between the at least two bonding wires connected to pads of the MEMS element, to detect a material deposit on the environmental sensor.

15. The environmental sensor according to claim 14, wherein one of the pads of the MEMS element to which a bonding wire used for ascertaining the parasitic capacitance is connected is not functionally connected at the MEMS element.

16. The environmental sensor according to claim 14, wherein two pads of the MEMS element to which a bonding wire used for ascertaining the parasitic capacitance is respectively connected are not functionally connected at the MEMS element.

17. The environmental sensor according to claim 14, wherein two pads of the MEMS element to which a bonding wire used for ascertaining the parasitic capacitance is respectively connected are functionally connected at the MEMS element.

18. The environmental sensor according to claim 14, wherein two pads of the MEMS element to which a bonding wire used for ascertaining the parasitic capacitance is respectively connected are terminal pads of a capacitive Wheatstone bridge circuit of the MEMS element, and wherein the evaluation circuit is configured to ascertain the parasitic capacitance through a capacitance measurement relating to a reference capacitance of the capacitive Wheatstone bridge circuit.

19. The environmental sensor according to claim 18, wherein the capacitive Wheatstone bridge circuit is a full bridge circuit or a half bridge circuit.

20. The environmental sensor according to claim 14, wherein the evaluation circuit is configured to determine, using a defined capacitance value, that no material deposit at all is present on the environmental sensor.

21. The environmental sensor according to claim 14, further comprising:
a signaling device using which a presence of a material deposit can be signaled.

22. The environmental sensor according to claim 14, wherein the evaluation circuit is configured to activate a device for removing liquid when liquid is detected.

23. The environmental sensor according to claim 14, wherein the environmental sensor is at least one of the following: liquid sensor, pressure sensor, gas sensor, humidity sensor, microphone.

24. A method for operating an environmental sensor, wherein the environmental sensor including a MEMS element including a first pad and a second pad, wherein a first bonding wire is connected to the first pad and a second bonding wire is connected to the second pad, the method comprising the following steps:
applying an electrical actuation signal to the first bonding wire, wherein the first bonding wire is capacitively coupled to the second bonding wire;
ascertaining a parasitic capacitance formed between the first and second bonding wires;
evaluating the ascertained parasitic capacitance; and
signaling a result of the evaluation.

25. The method according to claim 24, wherein at least the steps of applying the electrical actuation signal, ascertaining the parasitic capacitance and evaluating are carried out at defined points in time and/or cyclically.

26. A non-transitory computer-readable data carrier on which is stored a computer program with program code for operating an environmental sensor, wherein the environmental sensor including a MEMS element including a first pad and a second pad, wherein a first bonding wire is connected to the first pad and a second bonding wire is connected to the second pad, the program code, when executed by an ASIC element, causing the ASIC element to perform the following steps:
applying an electrical actuation signal to the first bonding wire, wherein the first bonding wire is capacitively coupled to the second bonding wire;
ascertaining a parasitic capacitance formed between the first and second bonding wires;
evaluating the ascertained parasitic capacitance; and
signaling a result of the evaluation.
